(19) United States
(12) Patent Application Publication
(10) Pub. No.: US 2015/0305192 A1
(43) Pub. Date: Oct. 22, 2015

(54) DIELECTRIC THERMAL PAD USING DUAL-SIDED THERMALLY CONDUCTIVE ADHESIVE ON CERAMIC

(71) Applicant: Tesla Motors, Inc., Palo Alto, CA (US)

(72) Inventors: William T. Chi, Mountain View, CA (US); Don Chiu, Santa Clara, CA (US); Christopher James TILTON, Palo Alto, CA (US)

(21) Appl. No.: 14/688,902

(22) Filed: Apr. 16, 2015

Related U.S. Application Data
(60) Provisional application No. 61/980,536, filed on Apr. 16, 2014.

(51) Int. Cl. H05K 7/20; B32B 37/12; B32B 38/10; B32B 37/18

(52) U.S. Cl. CPC H05K 7/2039; B32B 37/18; B32B 37/1284; B32B 38/10; B32B 2307/204; B32B 2457/00

(57) ABSTRACT

A device includes: an electronic component that generates heat; a heatsink configured to absorb at least part of the heat through thermal transfer; and a thermally conductive dielectric pad that attaches the electronic component and the heatsink to each other and facilitates the thermal transfer. The thermally conductive dielectric pad includes: a ceramic tile; a first layer of adhesive that attaches a first side of the ceramic tile to the electronic component; and a second layer of adhesive that attaches a second side of the ceramic tile to the heatsink.

### BACKGROUND

Some chargers and inverters have thermal grease and steel spring assemblies. In service, thermal grease can have a propensity to pump out under thermal cycling and may have dry-out and dilution interactions with surrounding gel encapsulants. Assembly on a production line using existing grease may require extensive tray and cover measures to prevent dust contamination, strings and drips onto other components, as well as cautious handling and insertion of both devices and tiles into the heatsink.

Existing thermal interface materials (TIMs) utilizing thermoset adhesives do not offer high dielectric strength without addition of film, which sacrifices thermal conductivity significantly. Generally, ceramics such as alumina or silicon nitride have not been commercially implemented as a highly-thermally conductive dielectric permanent pad solution. Another class of TIMs involves phase change and may provide very light room temperature adhesion characteristics. In a sense, they can be similar to wax, but upon heating to service temperatures they can re-liquefy and suffer the same, or worse, pump-out behavior as grease under thermal cycling.

### SUMMARY

In a first aspect, a device includes: an electronic component that generates heat; a heatsink configured to absorb at least part of the heat through thermal transfer; and a thermally conductive dielectric pad that attaches the electronic component and the heatsink to each other and facilitates the thermal transfer. The thermally conductive dielectric pad includes: a ceramic tile; a first layer of adhesive that attaches a first side of the ceramic tile to the electronic component; and a second layer of adhesive that attaches a second side of the ceramic tile to the heatsink.

Implementations can include any or all of the following features. The device further includes a spring that biases the electronic component and the heatsink toward each other. The device includes multiple electronic components each attached to one of multiple ceramic tiles, wherein the ceramic tiles form a tile panel. The thermally conductive dielectric pad essentially consists of the ceramic tile and the first and second layers of adhesive.

In a second aspect, a method includes: dispensing adhesive on first and second opposing sides of a ceramic tile; assembling an electronic component and the ceramic tile together so that a first layer of the adhesive attaches the first side of the ceramic tile to the electronic component; and assembling a heatsink and the ceramic tile together so that a second layer of the adhesive attaches the second side of the ceramic tile to the heatsink.

Implementations can include any or all of the following features. Dispensing the adhesive comprises forming respective beads of adhesive on the first and second opposing sides of the ceramic tile. Each of the beads is formed with an essentially circular periphery. The ceramic tile is one of multiple ceramic tiles that form a tile panel, the method further comprising dispensing adhesive on each of the ceramic tiles. The method further includes assembling each of multiple electronic components onto respective ones of the ceramic tiles after dispensing the adhesive on each of the ceramic tiles, and thereafter separating individual ceramic tiles from the tile panel. The method further includes separating individual ceramic tiles from the tile panel after dispensing the adhesive on each of the ceramic tiles, and thereafter assembling each of multiple electronic components onto respective ones of the ceramic tiles. The method further includes curing the adhesive. The adhesive is a pressure-sensitive adhesive and wherein curing the adhesive comprises applying pressure to the adhesive. Applying pressure to the adhesive comprises assembling a spring so that the electronic component and the heatsink are biased toward each other. The adhesive is a thermal adhesive and wherein curing the adhesive comprises applying heat to the adhesive. The heat is applied after the assembling steps. The method further includes allowing the adhesive to dry before performing the assembling steps.

In a third aspect, a method includes: positioning a ceramic tile so that a first surface thereof abuts an electronic component; positioning the ceramic tile so that a second surface thereof opposite to the first surface abuts a heatsink; and after at least positioning the first surface of the ceramic tile, applying a capillary-action adhesive between the electronic component and the ceramic tile so that the first surface and the electronic component attach to each other.

Implementations can include any or all of the following features. The ceramic tile is one of multiple ceramic tiles that form a tile panel, wherein electronic components are positioned on each of the ceramic tiles in the tile panel, and wherein the capillary-action adhesive is applied before the ceramic tiles are separated from each other. The method further includes separating the ceramic tile from the tile panel and placing the separated ceramic tile onto the heatsink. The method further includes applying a capillary-action adhesive between the heatsink and the ceramic tile so that the second surface and the heatsink attach to each other.

### BRIEF DESCRIPTION OF DRAWINGS

FIG. 1A shows a pre-applied adhesive deposited and dried onto a tile panel.

FIG. 1B shows electronic components affixed to the tile panel by the pre-applied adhesive.

FIG. 2A shows an electronic component and a ceramic tile on a heatsink before curing.

FIG. 2B shows the electronic component and the ceramic tile on the heatsink after curing.

### DETAILED DESCRIPTION

This document describes examples of using thermally conductive adhesive on each surface of a ceramic dielectric pad, wherein the pad is installed between a component and a heatsink. In some implementations, the adhesive is pre-applied on the ceramic pad, and the pad is thereafter assembled between the component and the heatsink. In other implementations, the pad is first assembled between the component and the heatsink, and a capillary-action adhesive is thereafter introduced on each side of the pad.

The adhesive is applied to create adhesion between, on the one hand, the component and the ceramic pad, and, on the other hand, between the ceramic pad and the heatsink. This description contemplates that different types of adhesive can be used. For example, and without limitation, a pressure-sensitive adhesive (PSA), a thermoset adhesive, and/or a multipart adhesive can be used.

A high thermal conductivity ceramic tile may have thermosetting or other pre-applied adhesive onto its surfaces for assembly and in-situ cure by heat activation. The result can be a permanent, high-thermal conductivity interface with high dielectric breakdown, such as is required in high-voltage applications. By using a ceramic tile, heat transfer is excellent and a solid barrier for high-voltage breakdown is provided. Certain implementations can decrease the cost and weight compared to existing approaches, while simplifying assembly.

In some implementations, a thermally filled adhesive is deposited onto the ceramic substrate on both sides and “dried” for shipment and handling. The adhesive may be thermoset or another pre-applied type. The dispense pattern may be selected to have any shape such as dots, a rectangle, or any other pattern that yields good flow and wetting of surfaces when curing. One or more thermal tiles are then assembled beneath at least one electrical component to be cooled. A certain external force can be applied in the assembly. If a pressure-activated adhesive (such as Part A & B micro-balloons) is sufficient to initiate cure, then external force alone may liquefy the adhesive compound whereby the component, the ceramic tile, and the heatsink become wetted with adhesive and cured in place. If the adhesive is a thermoset, baking the heatsink assembly at a certain activation temperature causes liquefaction and wetting, and the entire TIM stack may cure in place. In some implementations, the cured compound is cross-linked and permanently attaches the component.

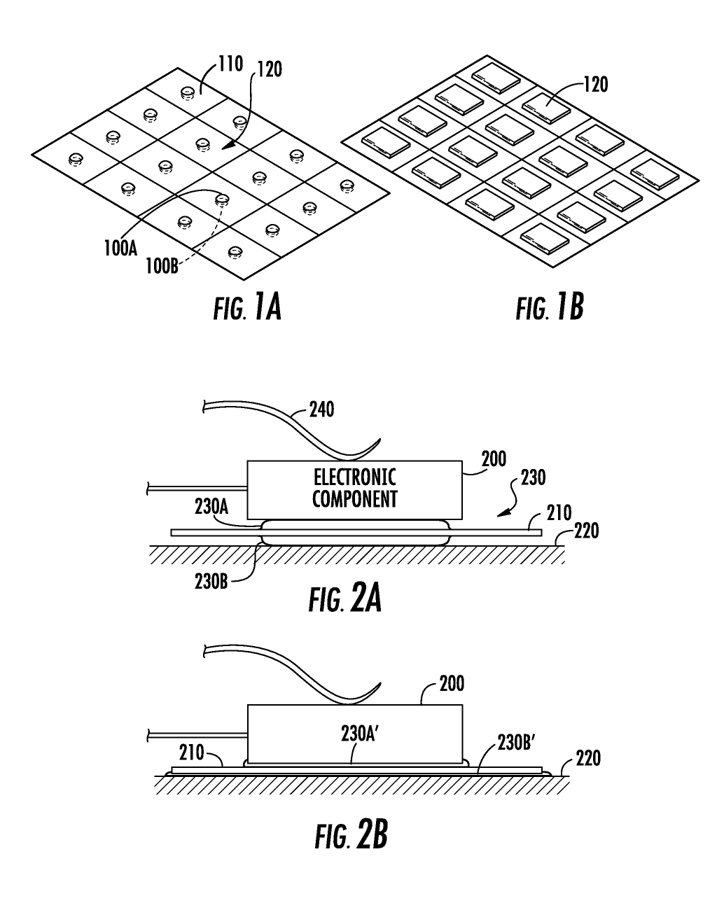

FIG. 1A shows a pre-applied adhesive 100 deposited and dried onto a tile panel 110. The adhesive is applied to both sides of the tile panel. Here, beads 100A are placed on the upper surface of the tile panel, and beads 100B are placed on the lower surface of the tile panel. For example, the bead can have an essentially circular periphery after being dispensed onto the tile panel. The tile panel includes multiple ceramic tiles. For example, the panel can have scores and/or performations that define the outlines of the individual ceramic tiles. Individual tiles can then be separated from the panel by breaking or cutting them off, for example.

FIG. 1B shows electronic components 120 affixed to the tile panel 100 by the pre-applied adhesive. The assembly can be done by placing the components on top of the adhesive on one side of the tile panel. Each tile or groups of tiles of the tile panel 100 may be snapped and installed for assembly.

In another embodiment, the adhesive is not pre-applied. Rather, a capillary-action adhesive is applied between the electronic component and the respective ceramic tile. In such implementations, the tile panel can be divided into individual ceramic tiles before the assembly, and then the capillary-action adhesive can be applied to each assembled stack.

FIG. 2A shows an electronic component 200 and a ceramic tile 210 on a heatsink 220 before curing. This arrangement is considered a thermal stack in that heat generated in the electronic component is intended to flow through the ceramic tile into the heatsink for purposes of thermal management. The electronic component can have one or more conductors or terminals extending from it in one or more directions, in this example substantially parallel with the heatsink. An adhesive 230 is applied to the ceramic tile. Here, the adhesive includes a first bead 230A facing the electronic component, and a second bead 230B facing the heatsink.

The adhesive can be applied using any suitable dispensing technique given its physical properties. In some implementations, the adhesive is pre-applied to the ceramic tile before assembly. For example, adhesive can be dispensed onto both sides of the ceramic tile before combining the tile with any of the electronic component and the heatsink. The electronic component can first be positioned onto the adhesive on one side of the tile, then the tile can be separated from the tile panel, and thereafter the tile can be attached onto the heatsink by way of the adhesive on the opposite side of the tile.

In other implementations, the electronic component, the ceramic tile and the heatsink can be assembled together without any adhesive initially being applied. Thereafter, such as immediately after that assembly process, a capillary-action adhesive can then be applied at the boundaries where the electronic component and the heatsink, respectively, meet the ceramic tile. For example, the adhesive can be applied on each side of the pad.

A spring 240 can be applied during assembly to apply a sufficient normal force for creating the necessary adhesion. The spring biases the electronic component and the heatsink toward each other. Any other approach that creates sufficient normal force can be used instead of a spring. The spring assembly can be removed after installation if the adhesion is proven reliable through testing. Some implementations may not need any additional normal force applied, and the spring assembly can then be omitted entirely.

FIG. 2B shows the electronic component 200 and the ceramic tile 210 on the heatsink 220 after curing. The adhesive 230 has formed respective thin layers 230A′ and 230B′ on opposite sides of the ceramic tile. Together, these layers and the ceramic tile form a permanent, high-thermal conductivity interface with high dielectric breakdown. The assembly is therefore suited for use in high-voltage applications. For example, the assembly can be used in a charger or an inverter. As such, the assembly can overcome or reduce the problems associated with pumping out of thermal materials that can otherwise occur during thermal cycling. As another example, the assembly can eliminate or reduce drying-out and dilution interactions, such as interaction with surrounding gel encapsulants, which can otherwise occur. As yet another example, with a pre-applied adhesive one can overcome or reduce challenges that could otherwise complicate the manufacturing process, such as preventing dust contamination.

A number of implementations have been described as examples. Nevertheless, other implementations are covered by the following claims.

What is claimed is:

1. A device comprising:
an electronic component that generates heat;
a heatsink configured to absorb at least part of the heat through thermal transfer; and
a thermally conductive dielectric pad that attaches the electronic component and the heatsink to each other and facilitates the thermal transfer, the thermally conductive dielectric pad comprising:
a ceramic tile;
a first layer of adhesive that attaches a first side of the ceramic tile to the electronic component; and
a second layer of adhesive that attaches a second side of the ceramic tile to the heatsink.

2. The device of claim 1, further comprising a spring that biases the electronic component and the heatsink toward each other.

3. The device of claim 1, comprising multiple electronic components each attached to one of multiple ceramic tiles, wherein the ceramic tiles form a tile panel.

4. The device of claim 1, wherein the thermally conductive dielectric pad essentially consists of the ceramic tile and the first and second layers of adhesive.

5. A method comprising:
dispensing adhesive on first and second opposing sides of a ceramic tile;
assembling an electronic component and the ceramic tile together so that a first layer of the adhesive attaches the first side of the ceramic tile to the electronic component; and
assembling a heatsink and the ceramic tile together so that a second layer of the adhesive attaches the second side of the ceramic tile to the heatsink.

6. The method of claim 5, wherein dispensing the adhesive comprises forming respective beads of adhesive on the first and second opposing sides of the ceramic tile.

7. The method of claim 6, wherein each of the beads is formed with an essentially circular periphery.

8. The method of claim 5, wherein the ceramic tile is one of multiple ceramic tiles that form a tile panel, the method further comprising dispensing adhesive on each of the ceramic tiles.

9. The method of claim 8, further comprising assembling each of multiple electronic components onto respective ones of the ceramic tiles after dispensing the adhesive on each of the ceramic tiles, and thereafter separating individual ceramic tiles from the tile panel.

10. The method of claim 8, further comprising separating individual ceramic tiles from the tile panel after dispensing the adhesive on each of the ceramic tiles, and thereafter assembling each of multiple electronic components onto respective ones of the ceramic tiles.

11. The method of claim 5, further comprising curing the adhesive.

12. The method of claim 11, wherein the adhesive is a pressure-sensitive adhesive and wherein curing the adhesive comprises applying pressure to the adhesive.

13. The method of claim 12, wherein applying pressure to the adhesive comprises assembling a spring so that the electronic component and the heatsink are biased toward each other.

14. The method of claim 11, wherein the adhesive is a thermal adhesive and wherein curing the adhesive comprises applying heat to the adhesive.

15. The method of claim 14, wherein the heat is applied after the assembling steps.

16. The method of claim 11, further comprising allowing the adhesive to dry before performing the assembling steps.

17. A method comprising:
positioning a ceramic tile so that a first surface thereof abuts an electronic component;
positioning the ceramic tile so that a second surface thereof opposite to the first surface abuts a heatsink; and
after at least positioning the first surface of the ceramic tile, applying a capillary-action adhesive between the electronic component and the ceramic tile so that the first surface and the electronic component attach to each other.

18. The method of claim 17, wherein the ceramic tile is one of multiple ceramic tiles that form a tile panel, wherein electronic components are positioned on each of the ceramic tiles in the tile panel, and wherein the capillary-action adhesive is applied before the ceramic tiles are separated from each other.

19. The method of claim 18, further comprising separating the ceramic tile from the tile panel and placing the separated ceramic tile onto the heatsink.

20. The method of claim 19, further comprising applying a capillary-action adhesive between the heatsink and the ceramic tile so that the second surface and the heatsink attach to each other.
